(19) United States
(12) Patent Application Publication
(10) Pub. No.: US 2001/0009202 A1
(43) Pub. Date: Jul. 26, 2001

(54) Direct attached board to board interconnection and method for forming same

(76) Inventors: Donald M. Metzelaar, Lindenhurst, IL (US); Kevin L. Kent, Woodstock, IL (US); Anthony J. Richter, Arlington Heights, IL (US)

Correspondence Address: MOTOROLA INC, 600 NORTH US HIGHWAY 45, LIBERTYVILLE, IL, 60048-5343, US

(21) Appl. No.: 09/819,383

(22) Filed: Mar. 28, 2001

Related U.S. Application Data
(62) Division of application No. 09/356,608, filed on Jul. 19, 1999.

(51) Int. Cl. H05K 1/09; H05K 1/11

(52) U.S. Cl. 174/255

(57) ABSTRACT

An interconnect for connecting two printed circuit boards (30, 32) directly together and a method for achieving same. A through hole (70) is formed in a first printed circuit board (30), which is surrounded by a conductive layer (62). A conductive layer (82) is also deposited on a second printed circuit board (32) opposite the through hole (70). The conductive layers (62, 82) allow for the conduction of electrical signals between and about the two printed circuit boards (30, 32). In the preferred embodiment, the conductive layer (62, 82) is copper metalization and the through hole (70) is plated with copper. A solder joint (58) is applied to fill the through hole (70) and establish electrical connection between the conductive layers (62, 82) on the two printed circuit boards (30, 32). Electrical connection is established by applying the solder joint (58) to and between the conductive layers (62, 82) on both boards (30, 32). In an alternative embodiment using a non-plated through hole (70), the interconnect is achieved by either repetitious localized impact, induced vibration or ultrasonic vibration applied to the solder joint (58) after the solder (56) is deposited.

### FIELD OF THE INVENTION

The present invention relates to methods and structures for interconnecting electrical devices, and more particularly, to a method and structure for directly connecting two printed circuit boards together.

### BACKGROUND OF THE INVENTION

More and more cellular products are moving towards single printed circuit board configurations where the single board incorporates both the transceiver and keypad circuits. In doing so, cellular products that use these single board designs lose flexibility in keypad layout options while attempting to maintain a common transceiver model and reducing costs. A single board based product usually has three options regarding keypad layout: (1) Create multiple transceiver models (multiple boards) with the only difference being keypad layout; (2) attach an auxiliary keypad to the common transceiver, which would reposition the keys; or (3) allow only one keypad option for the product to the customer.

The factory's ability to efficiently build products with multiple keypad options increases market flexibility; however, creating multiple transceiver models utilizing the same board complicates factory processes and inventory control. The single board approach correspondingly eliminates or prevents the production options currently enjoyed with two-board radios where limited numbers of transceiver models and proliferated keypad models are used. Allowing only one keypad option to the customer however is a disadvantage in that it limits a manufacturer's ability to capture market share.

With the thin profile requirements and cost saving initiatives of modern cellular telephones, a need arose to connect a keypad printed circuit board directly to a transceiver printed circuit board and eliminate the cost and complexity of additional board interconnect devices. However, most forms of printed circuit board interconnects are achieved using plated through-holes and matching copper patterns or through components, such as connectors. Hence, an innovative direct attached printed circuit board to printed circuit board interconnection would provide a more cost effective design alternative while maintaining assembly equipment and factory layouts. Directly attaching a keypad circuit board to a transceiver circuit board also overcomes some of the disadvantages associated with a single board design, such as the provision of multiple keypad layouts for the same telephone model.

### BRIEF SUMMARY OF THE INVENTION

In view of the above, a novel printed circuit board interconnect and method of forming the interconnect is provided. According to the method of the invention, a through hole is formed in a first printed circuit board, the through hole to receive a solder joint. A conductive material is then deposited at the periphery of the through hole to allow the conduction of electrical impulses. The conductive material is also deposited on a second printed circuit board at a position opposite to the through hole. A solder joint is applied within the through hole such that electrical contact is maintained between the solder joint the conductive material on the first printed circuit board. Electrical contact is also achieved between the solder joint and the conductive material on the second printed circuit board.

According to the apparatus of the invention, an interconnect is provided having a through hole formed in a first printed circuit board, the through hole to receive a solder joint. A first conductive pad, deposited at the periphery of the through hole, allows the conduction of electrical impulses. A second conductive pad is disposed on a second printed circuit board at a position opposite to the through hole. A solder joint, applied within the through hole, is included such that electrical contact is maintained between the solder joint and the conductive pad on the first printed circuit board, and the solder joint and the conductive pad on the second printed circuit board.

In one preferred embodiment of the invention, the through hole is internally plated with a conductive material. The conductive material readily receives and adheres to the solder joint. In an alternate embodiment, a non-plated through hole can be used. In such cases, inertial force is applied to the solder joint to ensure electrical contact between the two printed circuit boards. Examples of such force include repetitious direct local impact, vibration or ultrasound.

The present invention solves the need to interconnect thin printed circuit boards that otherwise cannot be attached using conventional surface mount technology (“SMT”) methods. The invention however is not limited to thin printed circuit boards, but can be applied to any product design requirements that need interconnect of printed circuit boards rather than the use of interconnect components. The invention could also be used for cellular telephones that require multiple key layouts within the same form factor.

The invention solves a need brought about by the challenges associated with cellular telephone miniaturization and designing keyboard functionality into the transceiver board. The integration approach of the invention thus accommodates a one-board radio which further improves the profit margin of the product.

The invention also provides for the use of an auxiliary keypad, which allows for the attachment of an inexpensive substrate to the main transceiver board in a cellular telephone. The auxiliary keypad substrate can contain only the desired keypad layout and electrical traces, which connects to the transceiver board. This allows the factory to build a single transceiver while allowing customer options on a variety of keypad layouts. The inexpensive substrate, or auxiliary keypad, can be packaged to auto-place and be assembled onto the transceiver board and attached via soldering. This technique eliminates the need for separate keypad lines to furnish a keypad kit to its respective transceiver line.

These and other features and advantages of the invention will become apparent upon review of the following detailed description of the presently preferred embodiments of the invention, taken in conjunction with the appended drawings.

### BRIEF DESCRIPTION OF SEVERAL VIEWS OF THE DRAWINGS

FIG. 1 shows the process steps of the front end assembly operation, where

FIG. 1(a) shows the prior art process, and

FIG. 1(b) shows the additional steps for interconnecting two printed circuit boards.

FIG. 2(a) illustrates a side view of an auxiliary keypad printed circuit board for connection to a transceiver board, and

FIG. 2(b) shows a top plan view of the presently preferred location for the through hole solder connection;

FIG. 3 is a side view of a soft beam process of creating the solder joint;

FIG. 4 illustrates in cross-section the detail of one fully formed interconnect structure;

FIG. 5 is a cross-sectional view of a keypad printed circuit board adjacent a transceiver printed circuit board, showing an empty through hole before formation of the interconnect;

FIG. 6 is a close-up cross-sectional view of the filling of the through hole shown in FIG. 5; and

FIG. 7 shows the deformation of the filled through hole shown in FIG. 6 in an alternate embodiment allowing for electrical interconnection of the two printed circuit boards.

### DETAILED DESCRIPTION OF THE PRESENTLY PREFERRED EMBODIMENTS OF THE INVENTION

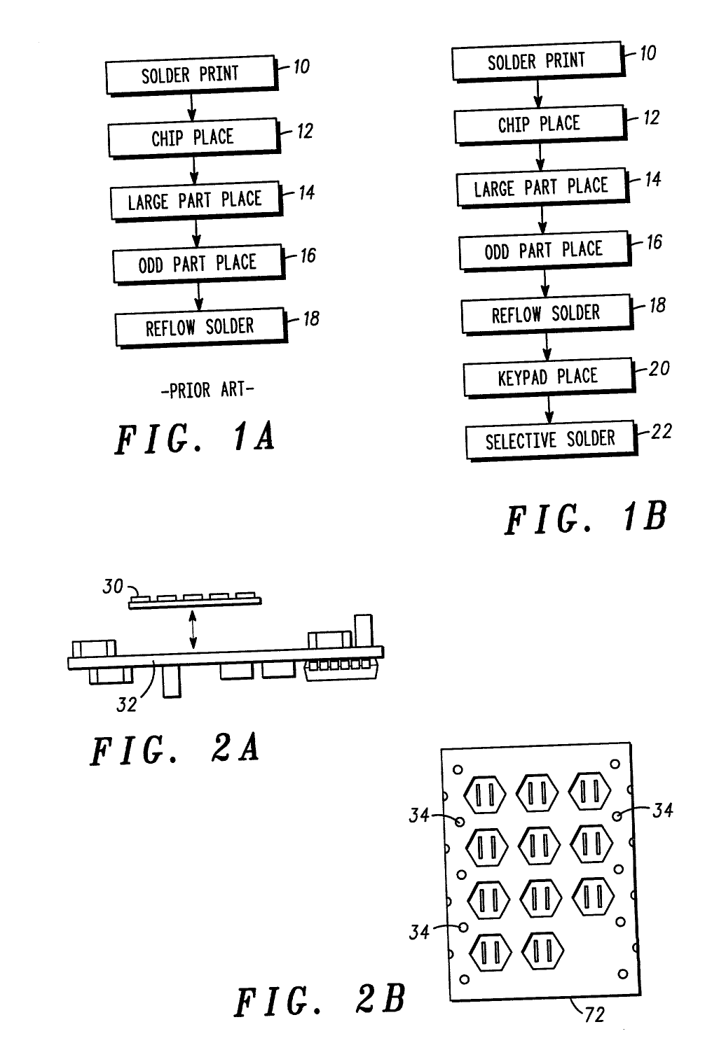

Referring to the drawings, where like elements receive like reference numerals throughout, a flow chart representing the presently preferred method of the invention is shown in FIG. 1. The prior art front-end assembly operation using a single board cellular telephone configuration is shown in FIG. 1(a). As can be seen, with a single printed circuit board, the steps of solder printing 10, chip placement 12, large part placement 14, odd part placement 16, and solder reflow 18 are performed if a combination keypad and transceiver is used. Using the interconnect device of the invention, two additional steps are added to the single printed circuit board front-end assembly process to accommodate a dual printed circuit board implementation, as shown in FIG. 1(b). After the solder reflow step 18 is performed, the secondary keypad circuit board is placed 20 adjacent to the primary transceiver circuit board, and a selective solder step is applied 22 to form a solder joint, as described in more detail below. As those skilled in the art will appreciate, although solder is described in the presently preferred embodiment of the invention, other substances are known in the art that can be used to implement the interconnect without departing from the spirit and scope of the invention.

Referring to FIG. 2, the keypad placement step 20 is preferably accomplished by auto-placing an auxiliary keypad substrate 30 onto a transceiver board 32 (see FIG. 2(a)). To achieve proper positioning of the auxiliary keypad substrate 30 for the selective soldering process (step 22), the auxiliary keypad substrate 30 may be preferably packaged with double-sided tape (not shown) on a relief liner (not shown). During the “pick” cycle, the auxiliary keypad substrate 30 is released from the relief liner prior to the placement cycle. For the selective solder process (step 22), selective heat and solder wire are applied to each connection 34 between the auxiliary keypad substrate 30 and the transceiver board 32, as shown in FIG. 2(b) and described in more detail below.

The selective soldering process, which is preferably a Soft Beam process, operates in the following manner. As illustrated in FIG. 3, the equipment 40 utilizes focused white light 42 and a solder wire feed mechanism 44. A lift and locate fixture (not shown) sandwiches and secures the auxiliary keypad substrate 30 to the transceiver board 32. A robotic end effector (not shown) positions the lens 46 and solder feed tube 48 over the targeted connection 34. The focused light 42 heats the area 54 surrounding the connection 34, and the solder feed mechanism 44 feeds solder wire 56 into the connection 34; hence, a solder joint 58 is formed. The process is repeated for the remainder of the connections 34 (see FIG. 2(b)).

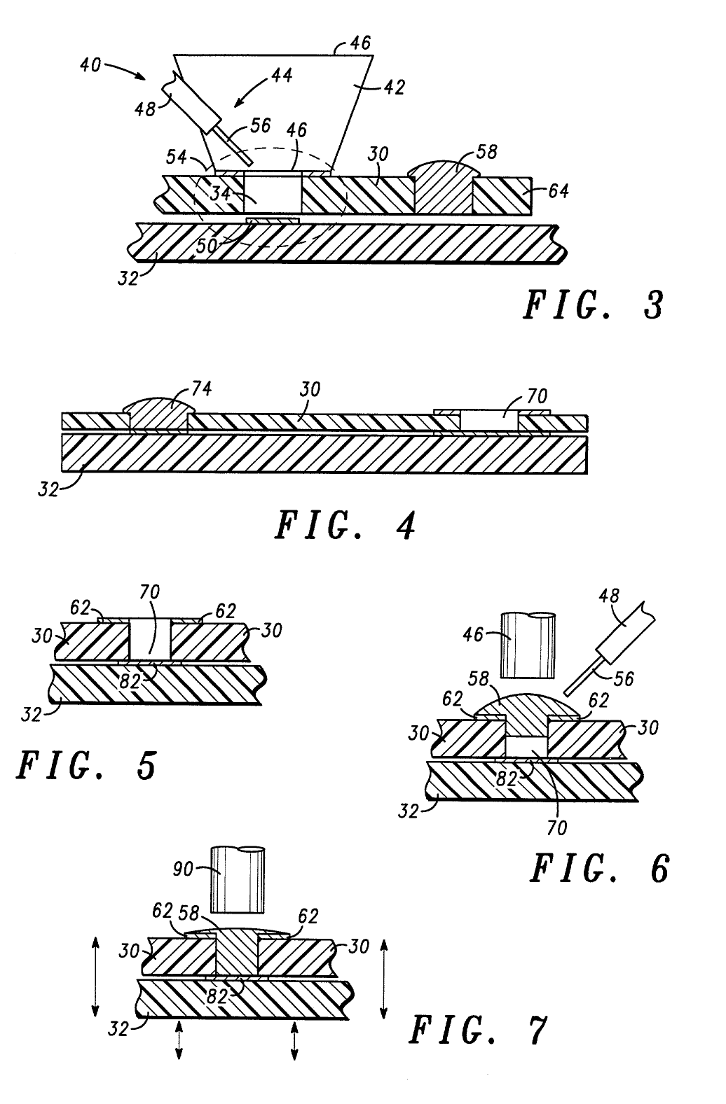

The auxiliary keypad substrate 30 is preferably composed of FR4 PW board material with etched copper patterns 62 and conductive keypads (not shown) disposed on one side 64. Referring to FIG. 4, plated or non-plated through holes 70 are strategically positioned near or on the edges 72 of the substrate 30 (see also FIG. 2(b)). Preferably, the through hole 70 is plated with copper although non-plated through holes 70 are also contemplated. The interconnect 74 between the substrate 30 and transceiver board 32 is accomplished by soldering the holes 70 and the copper patterns 62 on both the auxiliary keypad substrate 30 and transceiver board 32, as shown in FIG. 4, in the manner described above.

The keypad board 30 is preferably a thin single layer substrate, that is 0.010 inches thick. This substrate also preferably has nine holes leading to copper pads 82 on the transceiver board 32, as shown in FIGS. 2(b) and 5. The focused light solder system 40 shown in FIG. 3 is preferably used to heat the copper pads 62 on the keypad substrate 30. The focused light also transmits through the through holes 70 to the copper pads 82 located on the transceiver board 36. The solder feed mechanism 44 is preferably used to apply solder 56 to the pads 62 on the keypad substrate 30 (see FIG. 6). An adequate volume of solder 56 should be dispensed to cover both pads 62, 82 on each circuit board 30, 32 and fill each through hole 70. Once the solder 56 is applied to the pads 62, 82 and fills the through hole 70, the solder joint 58 forms the interconnect between the circuit boards 30, 32.

As those skilled in the art will appreciate, further cost savings could be realized by eliminating the preferred plated through-holes 70 on the single layer substrate 30. This poses a challenge, however, in forcing solder 56 through a non-plated through hole 70. To overcome the surface tension of the molten solder 58, and the non-wetting issues involved with non-plated through holes 70, a vibrational/impact device is preferably used to create an inertial force that drives the solder 54 through the through hole 70 to the transceiver board 32. The molten solder 58 further heats the transceiver pad 82 allowing the solder joint 58 to form. Several methods are contemplated to provide this inertial force. These methods include: (1) Repetitious localized impact via a tapping device 90 (i.e., cylinder up and down), as shown in FIG. 7; (2) induced vibration similar to bowl feeding technology (i.e., springs/magnetic coil); or (3) ultrasonic vibration.

As can be seen, the solder joint 58 provides an interconnect between electrical contacts on the two printed circuit boards 30, 32. The solder joint 58 is formed by filling one or more through holes 70 defined in the upper printed circuit board 30. Both plated and non-plated through holes 70 can be employed. With the interconnect 74 described above, multiple printed circuit boards can be interconnected to achieve low profile circuits for use in reduced height enclosures.

The foregoing description of the presently preferred embodiments of the present invention has been presented for purposes of illustration and description and is not intended to be exhaustive or to limit the invention to the precise form disclosed. Those skilled in the art will appreciate that many modifications and variations will be apparent, and that it is possible that the invention may be practiced in other fabrication technologies.

Similarly, any process steps described might be interchangeable with other steps in order to achieve the same result. The embodiments were described in order to best explain the principles of the invention and its practical application, thereby enabling others skilled in the art to understand the invention with various modifications as are suited to the particular use contemplated. It is therefore intended that the scope of the invention be defined by the claims appended hereto and all equivalents.

We claim:

1. A method for directly connecting a first printed circuit board (30) to a second printed circuit board (32), comprising the steps of:
forming a through hole (70) in the first printed circuit board (30), the through hole (70) to receive a solder joint (58);
depositing a conductive material (62) at the periphery of the through hole (70) to allow the conduction of electrical impulses;
depositing the conductive material (82) on the second printed circuit board (32) at a position opposite to the through hole (70);
applying a solder joint (58) within the through hole (70) such that electrical contact is maintained between the solder joint (58) and the conductive material (62) on the first printed circuit board (30); and
achieving electrical contact between the solder joint (58) and the conductive material (82) on the second printed circuit board (32).

2. The method defined in claim 1, wherein the step of achieving electrical contact comprises the step of applying ultrasonic vibration to the solder joint (58).

3. The method defined in claim 1, wherein the step of achieving electrical contact comprises the step of applying repetitious localized impact to the solder joint (58).

4. The method defined in claim 1, wherein the step of achieving electrical contact comprises the step of applying induced vibration to the solder joint (58).

5. The method defined in claim 1, further comprising the step of plating the through hole (70).

6. An interconnect for directly connecting a first printed circuit board (30) to a second printed circuit board (32), comprising:
a through hole (70) formed in the first printed circuit board (30), the through hole (70) to receive a solder joint (58);
a first conductive pad (62) deposited at the periphery of the through hole (70) to allow the conduction of electrical impulses;
a second conductive pad (82) deposited on the second printed circuit board (32) at a position opposite to the through hole (70); and
a solder joint (58) applied within the through hole (70) such that electrical contact is maintained between the solder joint (58) and the conductive pad (62) on the first printed circuit board (30), and the solder joint (58) and the conductive pad (82) on the second printed circuit board (32).

7. The interconnect defined in claim 5, wherein the first printed circuit board (30) comprises an auxiliary keypad substrate.

8. The interconnect defined in claim 5, wherein the second printed circuit board (32) comprises a transceiver board.

9. The interconnect defined in claim 5, wherein the first and second conductive pads (62, 82) comprise copper.

10. The interconnect defined in claim 5, wherein the through hole (70) is plated.

11. The interconnect defined in claim 5, wherein the through hole (70) is non-plated.

12. The interconnect defined in claim 5, wherein the through hole (70) comprises a plurality of through holes (70).

13. The interconnect defined in claim 9, wherein the plating comprises copper.
